(19) United States
(12) Patent Application Publication
(10) Pub. No.: US 2006/0220052 A1
(43) Pub. Date: Oct. 5, 2006

(54) LED lamp apparatus and manufacturing method thereof

(75) Inventors: Takayuki Kamiya, Aichi-ken (JP); Yoshio Sano, Aichi-ken (JP); Kazushi Noda, Aichi-ken (JP); Hiroshi Ito, Aichi-ken (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: TOYODA GOSEI, CO., LTD., Aichi-ken (JP)

(21) Appl. No.: 11/387,874

(22) Filed: Mar. 24, 2006

(30) Foreign Application Priority Data
Mar. 31, 2005 (JP) P2005-100973

(51) Int. Cl. H01L 33/00

(52) U.S. Cl. 257/99; 257/100; 257/E33.058

(57) ABSTRACT

In an LED lamp apparatus comprising an LED, a circuit portion and a case portion, a pair of the leads of the LED are surrounded at their parts by a sealing member and are extended to comprise the circuit portion, then at least one of the leads constituting the circuit portion is provided with a gap, and an element is disposed so as to extend over the gap.

This application is based on Japanese Patent Application No. 2005-100973, which is incorporated herein by reference.

### BACKGROUND OF THE INVENTION

1. Field of the Invention

The present invention relates to an LED lamp apparatus and the manufacturing method thereof.

2. Description of the Related Art

An example of the LED lamp apparatus is shown in JP-A-2003-258314.

As shown in FIG. 9, an LED lamp apparatus 101 includes an LED 102, a circuit portion 105, a terminal 107 and case portions 108, 109. The LED 102 has a pair of leads 103, 103 and a round type sealing member 104 which surrounds the base end portion of each of the leads. Alight emitting element is buried within the sealing member 104. The circuit potion 105 is formed by a metal plate and fixed to the inner case 108. Elements such as a resistor 106 are provided on the circuit portion 105. A reference numeral 107 denotes a terminal which is connected to the connector of a not-shown control apparatus. A reference numeral 109 in the figure denotes an outer case of a cylindrical shape. The inner case 108 is inserted into the outer case 109. The resistor 106 is provided in order to control a value of a current supplied to the LED 102.

According to the LED lamp apparatus 101 configured in this manner, since the metal plate is used instead of an expensive circuit board, the entire cost of the apparatus is cheap.

Another related technology relating to the invention is disclosed in JP-UM-A-5-62059.

### SUMMARY OF THE INVENTION

The inventors of the invention have made further structural improvement as to the LED lamp apparatus configured in the aforesaid manner thereby to investigate the reduction of the manufacturing cost thereof.

That is, an object of the invention is to provide an LED lamp apparatus with a new configuration.

Another object of the invention is to provide an LED lamp apparatus which can reduce the manufacturing cost thereof to a large extent.

The invention has been made in order to attain the aforesaid object. That is, an LED comprises a sealing member and a plurality of leads, the sealing member surrounding at least a part of the plurality of leads, a circuit portion comprising the plurality of leads being extended from the LED, at least one lead having a gap, and an element being attached to the at least one lead so as to bridge the gap, and a case portion.

According to the LED lamp apparatus configured in this manner, since the leads of the LED are extended to comprise the circuit portion, it is not necessary to provide a board nor a metal plate for configuring the circuit portion. That is, the number of the parts can be reduced and the manufacturing cost of the LED lamp apparatus can also be reduced.

Further, since it becomes possible to lay an arbitrary element over the gap by providing the gap at the lead, the degree of freedom for designing the circuit portion can be secured. Thus, the LED lamp apparatus suitable for the practical use can be obtained.

Such the circuit portion is preferably formed within the case portion. Since the circuit portion is protected by the case portion, the circuit portion is excellent in the durability.

A resistor can be raised as an example of the element laid over the gap. When the light emitting efficiency varies among the light emitting elements, the light emission amount of the light emitting element can be adjusted by adjusting a resistance value of the resistor connected in series with the light emitting element.

The LED lamp apparatus can be manufactured in the following manner.

That is, a method of manufacturing an LED lamp comprises preparing an LED comprising a sealing member and a plurality of leads, at least a part of the plurality of leads being surrounded by the sealing member, at least one lead having a gap and a detour portion which detours the gap, setting the plurality of leads to a case portion, attaching an element to the at least one lead so as to bridge the gap thereby forming a circuit portion, and removing the detour portion.

According to the manufacturing method, even if the lead has the gap, since the lead is provided with the detour portion, the lead has the unit or integral configuration. Thus, the lead can be treated easily and also set easily to the case portion.

In the aforesaid configuration, the detour portion serves to connect the lead portions (the lead portion on the light emitting element side and the lead portion on the free end side) divided via the gap, and so the detour portion may be formed integrally with the lead or formed separately from the lead. When the detour portion is configured so as to be formed integrally with the lead and developed on the same plane as the lead, the lead including such the detour portion can be formed by the single stamping operation.

Preferably, such the detour portion is developed on the same plane as the lead and has a U-shape. Since the detour portion is formed in the U-shape, the element can be laid over the detour portion in a manner that the terminals of the element are respectively joined at the corresponding portions of the opposed parallel transversal sides of the U-shaped configuration. Further, since the remaining longitudinal side of the U-shaped configuration is formed in a linear shape, the detour portion can be formed easily by stamping a metal plate.

Further, preferably, the element is laid on the lead after setting the leads having such the detour portion to the case portion. Thus is because, since the leads are supported by the case portion, the fixing operation of the element to the lead can be performed stably and so the yield can be improved.

Further, preferably, the detour portion is removed after laying the element on the lead. This is because when the detour portion is removed before fixing the element to the lead, the number of parts increases and so the procedure for positioning the parts increases.

In the aforesaid configuration, the type of the LED is not limited to a particular one. That is, in place of the round type exemplarily shown in the embodiments, a chip type may be used.

The light emission color of the LED can be selected arbitrarily. That is, in place of the blue used in the embodiments, an LED having the light emission wavelength of a visible region such as white, red, orange, green may be employed. Further, an LED having the light emission wavelength of an ultraviolet region may be employed. In this case, fluorescent material which fluoresces in response to the light of the ultraviolet region may be used together with the LED, and the fluorescent light can be used as an illumination light. The fluorescent material may be included in the sealing member (a round type portion) disposed on the light emission side of the LED, for example. A layer including the fluorescent material may be provided on the surface of the sealing member.

The combination of different kinds of LEDs and/or the combination of LEDs of different light emission colors may be used.

The sealing member mainly serves to cover the light emitting element and is formed by translucent material which is selected arbitrarily in accordance with a use and a purpose of the sealing member. The sealing member is preferably configured to have a portion of a lens shape in view of converging the light from the light emitting element.

A pair of the leads are provided so as to extend from the LED. One of the leads is coupled to a p-type electrode of the element within the LED and the other of the leads is coupled to an n-type electrode of the element.

The leads are surrounded by the sealing member at a base end side (a light emitting element side) thereof. The portions of the leads protruded from the sealing member are extended than those of the related leads thereby to comprise the circuit portion. The most required element as the element constituting the circuit portion of the LED is the resistor element. The resistor element is disposed in series with the light emitting element of the LED. In order to serially dispose the resistor, the lead is provided with the gap and the resistor element is laid over the gap in a manner that the both ends of the resistor element are joined to the lead portions at the opposite both ends of the gap. A diode may be laid over the gap in place of the resistor element or together with the resistor element.

A plurality of the gaps can be provided at the lead. In this case, the detour portion is provided at each of the gaps. One or at least two gaps and one or at least two detour portions thereof can be provided at each of the pair of leads.

The shape and the material of the leads can be arbitrarily selected so long as the leads have electrical conductivity. The lead is preferably formed by a metal thin plate in view of the mass-productivity and the manufacturing cost.

The circuit portion can be designed arbitrarily in accordance with a use and a purpose of the LED lamp apparatus.

The free end side of each of the leads comprises a terminal. The terminal can be designed arbitrarily in accordance with the specification of a partner-side connector.

Further, the shape and the material of the case portion can be arbitrarily selected in accordance with a use and a purpose of the LED lamp apparatus. The case portion is preferably a die formed product of composite resin in view of the mass-productivity, the light-weight properties and the manufacturing cost, etc.

### BRIEF DESCRIPTION OF THE DRAWINGS

FIG. 1 is a plan view showing a structure of an LED according to an embodiment of the invention;

FIG. 2 is a diagram showing the treatment mode of the LED according to the embodiment in the manufacturing process;

FIG. 3 is a perspective view showing a step of fixing the leads of the LED according to the embodiment to a case portion;

FIG. 4 is a diagram showing the treatment mode of a resistor element in the manufacturing process;

FIG. 5 is a perspective view showing a step of joining the resistor element to the lead;

FIG. 6 is a perspective view showing a step of removing a detour portion from the lead;

FIG. 7 is an exploded perspective view showing the structure of an LED lamp apparatus according to the embodiment;

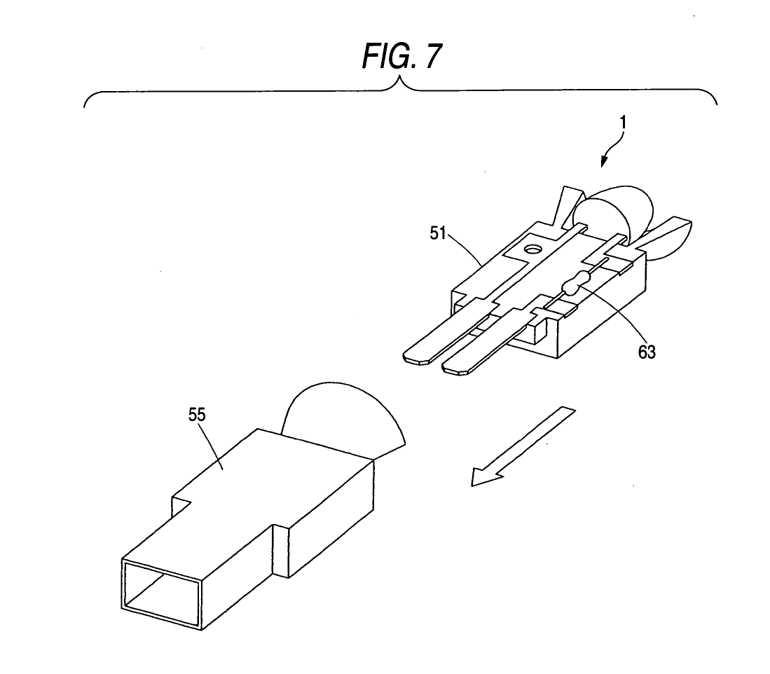

FIG. 8 is a plan view showing the structure of an LED according to another embodiment; and

FIG. 9 is an exploded view showing the structure of a related LED lamp apparatus.

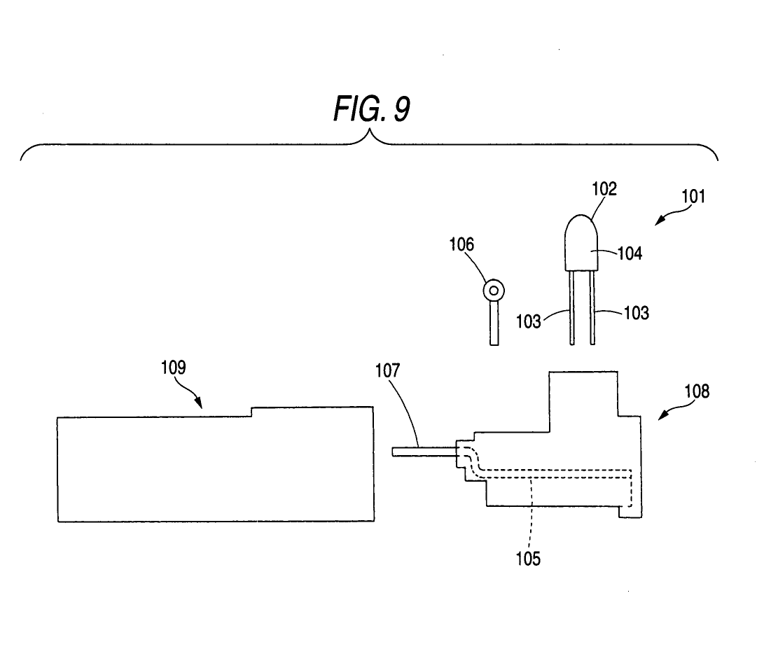

### DETAILED DESCRIPTION OF THE PREFERRED EMBODIMENTS

Embodiments of the invention will be explained hereinafter.

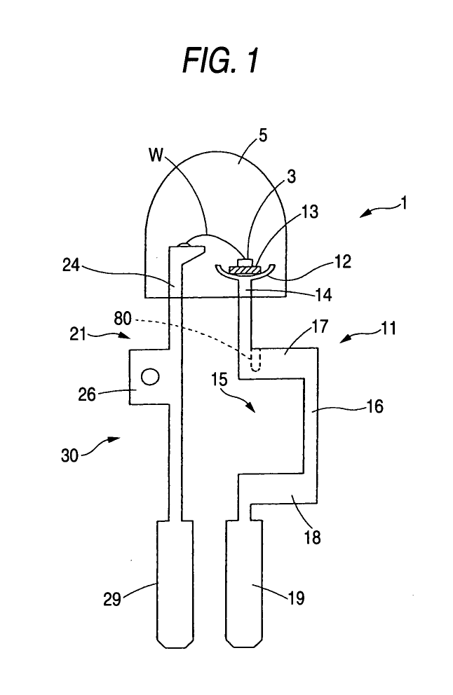

An LED 1 according to the embodiment is shown in FIG. 1.

The LED 1 includes a light emitting element 3, a sealing member 5, a lead 11 and a lead 21. As the light emitting element 3, a blue light emitting diode formed by group III nitride compound semiconductor is employed. The sealing member 5 is formed by transparent epoxy resin and die formed in a round type shape.

The lead 11 has a reflection dish 12 and the light emitting element 3 is mounted on the reflection dish 12 via a board 13. A Zener diode is disposed on the board 15 so as to be in parallel to the light emitting element 3 and in a reverse manner with respect to its forward voltage direction.

The lead 11 is provided with a gap 15 on the way thereof and further provided with a U-shaped detour portion 16 which extends around this portion. An element is laid between the opposed sides 17, 18 of the detour portion 16. A reference numeral 19 denotes a terminal.

In this embodiment, although the lead 21 is not provided with a gap nor a detour portion, it is possible to provide the gap and the detour portion at this lead. A reference numeral 29 in the figure denotes a terminal. According to this embodiment, terminals 19 and 29 comprise a terminal which is connected to a not-shown partner-side connector. A reference numeral 26 in the figure denotes a pedestal used for positioning.

In the lead 11, a base end side portion 14 continuing to the reflection dish 12 is formed to have a thin width like the related LED. Similarly, the base end side portion 24 of the lead 21 is formed to have a thin width like the related LED. Each of such the base end side portions 14, 24 has the same structure as the related lead.

In this embodiment, a thin metal plate is provided so as to extend from each of the base end side portions 14, 24 to comprise a circuit portion 30.

Each of the leads 11 and 21 is formed by stamping a thin metal plate.

The base end side portion of each of the leads 11 and 21 is surrounded by the sealing member 5.

The light emitting element 3 is mounted on the reflection dish 12 of the lead 11 and a bonding wire W is provided so as to extend from the light emitting element 3 to the lead 21. These component elements are set within a round type cavity as inserts and material of the sealing member 5 is injected into the cavity thereby to form the LED 1 shown in FIG. 1.

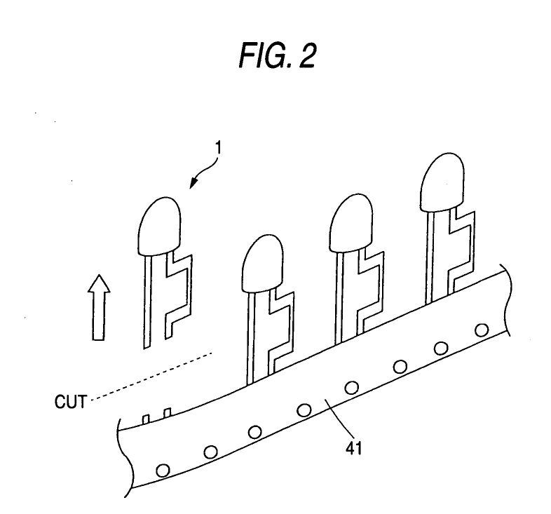

The LEDs 1 each formed in this manner as shown in FIG. 1 are disposed on a paper tape 41 in a line as shown in FIG. 2. At the time of using the LED, the leads 11 and 21 thereof are cut at their predetermined positions.

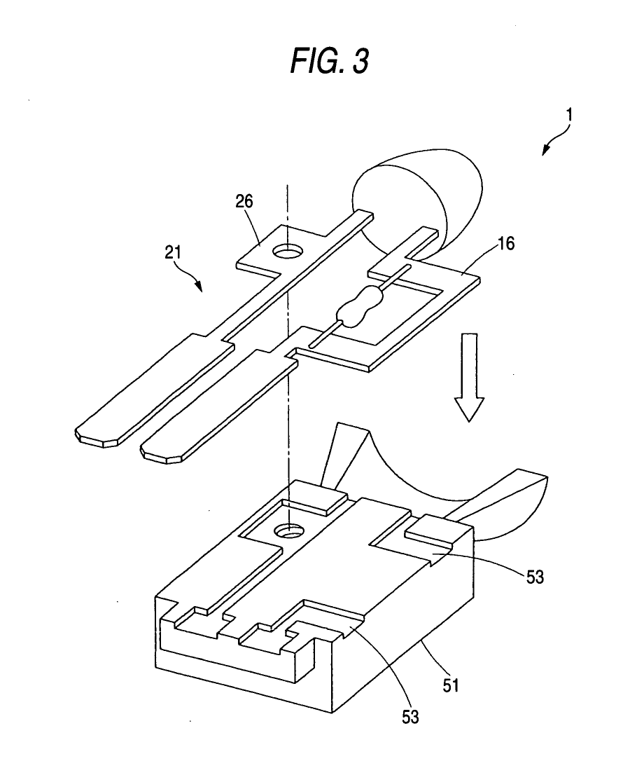

The LED 1 thus cut is set on the lower case 51 of a case portion as shown in FIG. 3. In this embodiment, the lead 21 of the LED 1 is fixed to the lower case 51 by the heat caulking. The lead 11 is forcedly fit into a concave portion 53 formed on the upper surface of the lower case 51, whereby the lead 11 is stably supported by the lower case 51. Incidentally, the lead 11 and/or the lead 21 may be fixed to the lower case 51 by an adhesive.

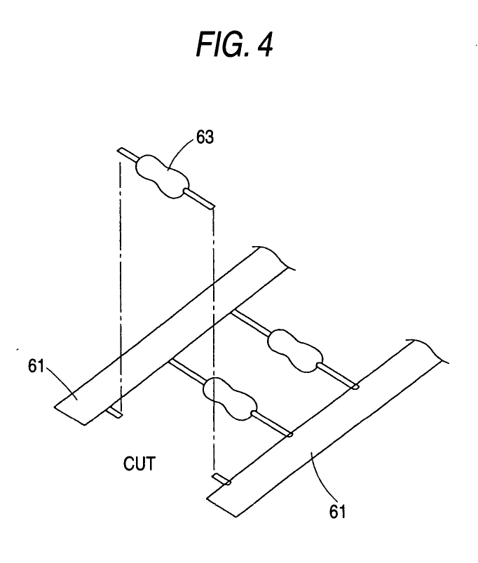

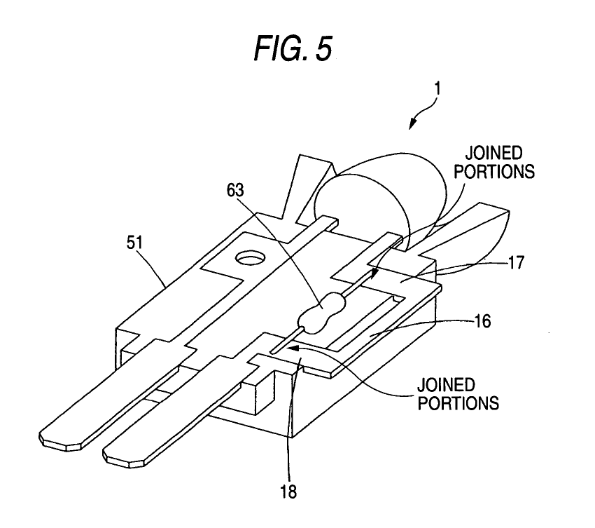

On the other hand, a resistor element 63, which both ends are respectively fixed to paper tapes 61, 61, is cut out as shown in FIG. 4 and its both ends are respectively soldered to the opposed sides 17, 18 of the U-shaped detour portion 16 so that the resistor element is laid therebetween as shown in FIG. 5. In this case, the resistor element 63 is located at the inside of the lower case 51. Since the lead 11 is supported by the lower case 51, the positioning and joining procedures of the resistor element 63 can be performed stably.

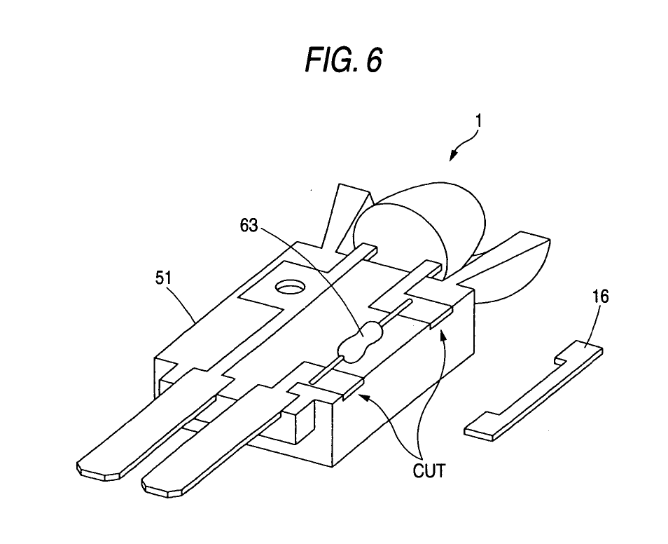

Thereafter, as shown in FIG. 6, a part of the detour portion 16 protruded from the lower case 51 is removed. In this embodiment, the protruded portion is cut by a die. Alternatively, the protruded portion may be cut in a manner that the detour portion 16 is provided with thin thickness portions so that the protruded portion is separated by bending the detour portion at the thin thickness portions.

An assembly of the LED1, the lower case 51 and the resistor element 63 obtained in this manner is inserted into an outer case 55, whereby the LED lamp apparatus according to the embodiment can be obtained.

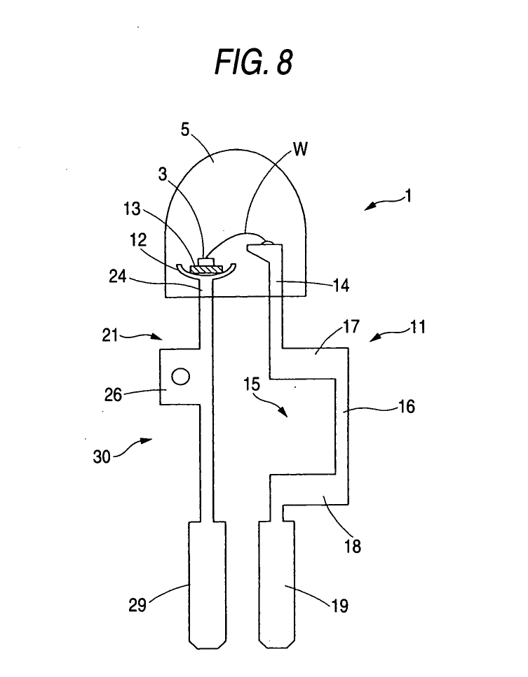

In this embodiment, the light emitting element is mounted on the lead side having the gap. Alternatively, as shown in FIG. 8, the light emitting element 3 may be mounted on a lead 24 having no gap. When the light emitting element is mounted on the lead having no gap, the degree of influence of heat generated from the resistor element on the light emitting element can be reduced. Incidentally, in FIG. 8, composition elements identical to those of FIG. 1 are referred to by the same symbols, with explanation thereof being omitted.

Similarly, the lead 11 may be provided with a notch (cut) 80 as shown by a dotted line in FIG. 1 so that heat generated from the resistor element does not influence on the light emitting element.

The invention is not limited to the aforesaid mode and embodiment of the invention. The invention contains various modifications which can be easily thought of for those skilled in the art within a range not departing from the scope of the invention.

What is claimed is:

1. An LED lamp apparatus comprising:
an LED comprising a sealing member and a plurality of leads, the sealing member surrounding at least a part of the plurality of leads;
a circuit portion comprising:
the plurality of leads being extended from the LED, at least one lead having a gap; and
an element being attached to the at least one lead so as to bridge the gap; and
a case portion.

2. The LED lamp apparatus according to claim 1, wherein the circuit portion is formed within the case portion.

3. The LED lamp apparatus according to claim 1, wherein the element comprises a resistor.

4. The LED lamp apparatus according to claim 1, wherein the plurality of leads comprise a pair of leads.

5. The LED lamp apparatus according to claim 1, wherein at least one lead having no gap comprises a pedestal for positioning the LED.

6. The LED lamp apparatus according to claim 1,
wherein the case portion comprises a lower case and an outer case, and
wherein the plurality of leads are set to the lower case, and the LED, the lower case and the element are inserted into the outer case.

7. A method of manufacturing an LED lamp comprising:
preparing an LED comprising a sealing member and a plurality of leads, at least a part of the plurality of leads being surrounded by the sealing member, at least one lead having a gap and a detour portion which detours the gap;
setting the plurality of leads to a case portion;
attaching an element to the at least one lead so as to bridge the gap thereby forming a circuit portion; and
removing the detour portion.

8. The method of manufacturing an LED lamp apparatus according to claim 7, wherein the detour portion is formed in a substantially U-shape.

9. The method of manufacturing an LED lamp apparatus according to claim 7, wherein the element is attached to the at least one lead after setting the leads to the case portion.

10. The method of manufacturing an LED lamp apparatus according to claim 9, wherein the detour portion is removed after attaching the element to the at least one lead.

11. The method of manufacturing an LED lamp apparatus according to claim 7, wherein the plurality of leads comprise a pair of leads.

12. The method of manufacturing an LED lamp apparatus according to claim 7,
wherein the case portion comprises a lower case and an outer case, and
wherein the method comprises setting the plurality of leads to the lower case, and inserting the LED, the lower case and the element into the outer case.

13. An LED lamp apparatus comprising:
an LED comprising a sealing member and a plurality of leads, the sealing member surrounding at least a part of the plurality of leads; and
a circuit portion comprising the plurality of leads being extended from the LED.
